(19) United States
(12) Patent Application Publication
(10) Pub. No.: US 2011/0129992 A1
(43) Pub. Date: Jun. 2, 2011

(54) METHOD FOR FABRICATING VERTICAL CHANNEL TYPE NON-VOLATILE MEMORY DEVICE

(76) Inventor: Young-Kyun JUNG, Gyeonggi-do (KR)

(21) Appl. No.: 12/647,163

(22) Filed: Dec. 24, 2009

(30) Foreign Application Priority Data
Nov. 30, 2009 (KR) 10-2009-0117439

(51) Int. Cl. H01L 21/8234

(52) U.S. Cl. 438/587; 257/E21.629

(57) ABSTRACT

A method for fabricating a vertical channel type non-volatile memory device includes repeatedly forming stacks of conductive layers and inter-layer insulation layers over a substrate, and performing an etch process using an etch gas which etches both the conductive layers and the inter-layer insulation layers to form a contact hole exposing the substrate, wherein the etch gas maintains a selectivity between the inter-layer insulation layers and the conductive layers with a ratio of different etching rates ranging from approximately 0.1 to approximately 2.

### CROSS-REFERENCE TO RELATED APPLICATIONS

The present application claims priority of Korean Patent Application No. 10-2009-0117439, filed on Nov. 30, 2009, which is incorporated herein by reference in its entirety.

### BACKGROUND OF THE INVENTION

Exemplary embodiments of the present invention relate to a method for fabricating a semiconductor device, and more particularly, to a method for fabricating a vertical channel type non-volatile memory device.

Memory devices may be generally classified into volatile memory devices and non-volatile memory devices, depending on the ability to maintain data when the power supply is cut off. The volatile memory devices include memory devices in which data are lost when the power supply is cut off. The volatile memory devices include dynamic random access memory (DRAM) and static random access memory (SRAM). The non-volatile memory devices include memory devices in which data are maintained when the power supply is cut off. The non-volatile memory devices also include flash memory devices.

In particular, a charge trap type non-volatile memory device includes a tunnel insulation layer, a charge trap layer, a charge barrier layer, and a control gate electrode formed over a substrate. The charge trap type non-volatile memory device stores data by trapping charges in a deep level trap site in the charge trap layer.

However, in the case of a typical flat plate type non-volatile memory device, there is a limit to improving the integration scale of the memory device. Consequently, vertical channel type non-volatile memory device, where cell strings are arrayed vertically from a substrate, is introduced. The vertical channel type non-volatile memory device includes a stack structure of a low select gate, a plurality of memory cells, and an upper select gate formed over a substrate. The vertical channel type non-volatile memory device may increase the integration scale through the use of cell strings arrayed vertically from the substrate.

Forming the vertical channel type non-volatile memory device may include repeatedly forming conductive layers and insulation layers, etching the repeatedly formed conductive layers and insulation layers using a hard mask as an etch barrier to form a trench in the middle of the structure, and burying a conductive material for forming a channel over the trench.

At this time, the conductive layers and the insulation layers are etched using different etch gases from each other. For instance, when the conductive layers include polysilicon, a gas including hydrogen bromide (HBr) and chlorine (Cl₂) may be used to etch the conductive layers, and when the insulation layers include oxide-based layers, difluoromethane (CH₂F₂) gas may be used to etch the insulation layers.

However, when the conductive layers and the insulation layers are etched each using a different gas as described above, different etch rates of the conductive layers and the insulation layers cause the etched conductive layers and the etched insulation layers to become uneven, resulting in a staircase-like formation.

FIG. 1 illustrates micrographic views showing limitations of a typical method for fabricating a vertical channel type non-volatile memory device.

Referring to FIG. 1, when stack structures of conductive layers and insulation layers are etched using different etch gases for the conductive layers and the insulation layers, a staircase-like structure 100 is formed.

When a staircase-like structure is formed as described above, a bowing effect may result when burying a conductive material for forming a subsequent channel, or the surface area of a gate may decrease when forming an insulation layer on a sidewall due to the stepped formation, which may be unfavorable to device characteristics.

### SUMMARY OF THE INVENTION

Exemplary embodiments of the present invention are directed to a method for fabricating a vertical channel type non-volatile memory device, which can prevent formation of a staircase-like shape, which may be generated due to an etch rate difference during an etch process of a stack structure including different materials.

In accordance with an embodiment of the present invention, a method for fabricating a vertical channel type non-volatile memory device includes repeatedly forming stacks of conductive layers and inter-layer insulation layers over a substrate, and performing an etch process using an etch gas which etches both the conductive layers and the inter-layer insulation layers to form a contact hole exposing the substrate, wherein the etch gas maintains a selectivity between the inter-layer insulation layers and the conductive layers with a ratio of different etching rates ranging from approximately 0.1 to approximately 2.

The conductive layers may include polysilicon, and the inter-layer insulation layers may include oxide-based layers.

The etch gas may include tetrafluoromethane (CF₄) gas. The performing of the etch process to form the contact hole may include adding helium (He) gas to the etch gas. The performing of the etch process to form the contact hole may include adding nitrogen (N) gas to the etch gas.

The stacks may be repeatedly formed approximately 2 to 128 times. Each stack may have a thickness ranging from approximately 100 Å to approximately 1,000 Å.

After the performing of the etch process to form the contact hole, the method may further include forming gate insulation layers on sidewalls of the contact hole, and burying a conductive material over the contact hole to form a channel.

The gate insulation layers may include a three-layered structure of oxide/nitride/oxide. The conductive material may include polysilicon.

### BRIEF DESCRIPTION OF THE DRAWINGS

FIG. 1 illustrates micrographic views showing limitations of a typical method for fabricating a vertical channel type non-volatile memory device.

FIGS. 2A to 2E illustrate cross-sectional views of a method for fabricating a vertical channel type non-volatile memory device in accordance with a first embodiment of the present invention.

FIGS. 3A to 3G illustrate cross-sectional views of a method for fabricating a vertical channel type non-volatile memory device in accordance with a second embodiment of the present invention.

FIG. 4 illustrates a micrographic view showing stack structures in accordance with the embodiments of the present invention.

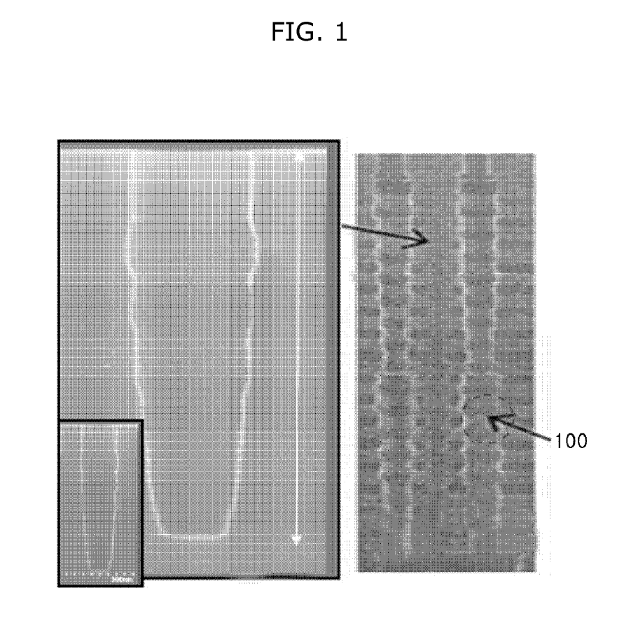

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate.

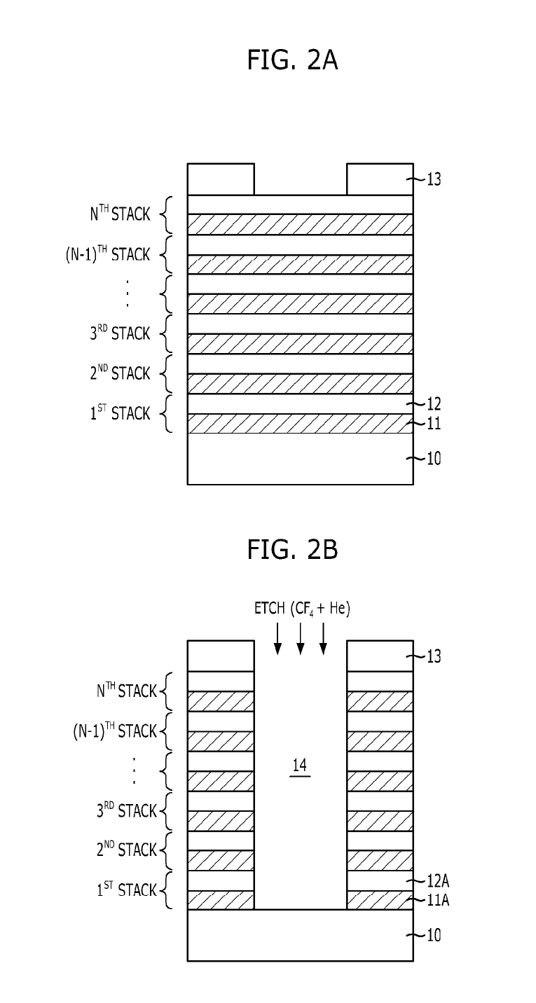

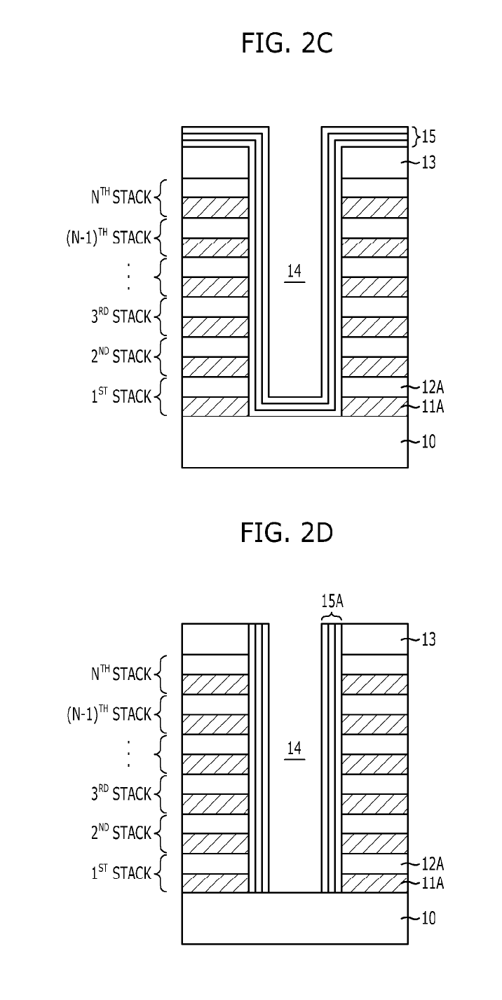

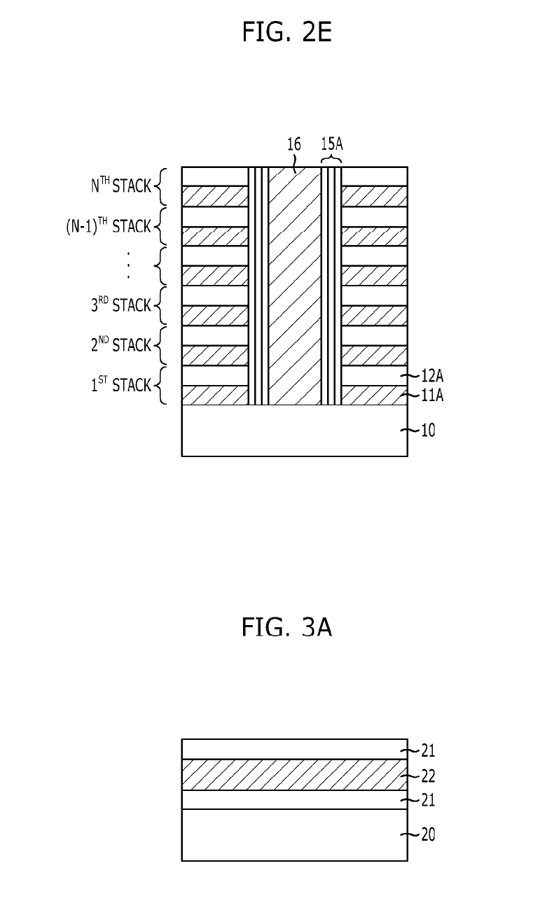

FIGS. 2A to 2E illustrate cross-sectional views of a method for fabricating a vertical channel type non-volatile memory device in accordance with a first embodiment of the present invention.

Referring to FIG. 2A, conductive layers 11 for forming gate electrodes and inter-layer insulation layers 12 are alternately formed over a semi-finished substrate 10. The semi-finished substrate 10 generally includes required bottom structures, such as source lines and low select gates. The conductive layers 11 are formed to create memory cells using a subsequent etch process. The conductive layers 11 include a conductive material. For instance, the conductive layers 11 may include polysilicon. The inter-layer insulation layers 12 are formed to provide inter-layer insulation between the subsequently formed memory cells. For instance, the inter-layer insulation layers 12 may include oxide-based layers.

One conductive layer 11 and one inter-layer insulation layer 12 configure a stack, and the stacks are stacked to form a cell string. At this time, each of the conductive layers 11 and the inter-layer insulation layers 12 has a thickness ranging from approximately 50 Å to approximately 500 Å. Therefore, one stack, including one conductive layer 11 and one inter-layer insulation layer 12, has a thickness ranging from approximately 100 Å to approximately 1,000 Å.

As semiconductor devices are becoming highly integrated, the number of stacks being stacked generally needs to be increased in order to include a larger number of memory cells in one cell string. Therefore, the stacks each including one conductive layer 11 and one inter-layer insulation layer 12 are repeatedly formed to form 1^{st}, 2^{nd}, 3^{rd}, (N−1)^{th}, and N^{th} stacks, where N is any positive integer. For instance, the stacks may be repeatedly formed approximately 2 to 128 times.

A hard mask pattern 13 is formed over the stacks including the alternately formed conductive layers 11 and inter-layer insulation layers 12. The hard mask pattern 13 is formed to etch the inter-layer insulation layers 12 and the conductive layers 11. The hard mask pattern 13 may be formed using a material having a relatively high etch selectivity with respect to the conductive layers 11 and the inter-layer insulation layers 12. For instance, the hard mask pattern 13 may include amorphous carbon.

For example, the hard mask pattern 13 is created by first forming a hard mask layer over the stacks. Then, a photoresist layer is formed over the hard mask layer. Next, a photo-exposure process is performed to pattern the photoresist layer, thereby forming a photoresist pattern exposing a channel region. Finally, the hard mask layer is etched using the photoresist pattern as an etch barrier to form the hard mask pattern 13. When forming the hard mask pattern 13 including amorphous carbon, a silicon oxynitride (SiON) layer may be formed as a hard mask for etching amorphous carbon. When forming the photoresist pattern, a bottom anti-reflective coating (BARC) layer may be additionally formed to prevent reflection.

Referring to FIG. 2B, the inter-layer insulation layers 12 (FIG. 2A) and the conductive layers 11 (FIG. 2A) are etched using the hard mask pattern 13 as an etch barrier to form a contact hole 14 for forming a channel, and memory cells 11A each insulated by a corresponding inter-layer insulation pattern 12A.

For instance, the conductive layers 11 and the inter-layer insulation layers 12 are etched at substantially the same time using one etch gas, rather than separately etching each layer.

Thus, an etch gas which etches both the inter-layer insulation layers 12, including oxide-based layers, and the conductive layers 11, including polysilicon, may be used. Also, a gas which may maintain a selectivity (for example, a selectivity of different etching rates) between the inter-layer insulation layers 12 and the conductive layers 11, for example, with a ratio of the different etching rates ranging from approximately 0.1 to approximately 2, may be used. For instance, the etch gas may include tetrafluoromethane (CF₄) gas. Etch reactions resulting from the use of CF₄ gas are as follows.

When etching polysilicon using CF₄ gas, CF₄ combines with silicon (Si) to generate silicon fluoride (SiF) while the etching process progresses (CF₄+Si→SiF). When etching oxide using CF₄ gas, CF₄ combines with silicon dioxide (SiO₂) to generate carbon dioxide (CO₂) and SiF while the etching process progresses (CF₄+SiO₂→CO₂+SiF). Thus, it may be possible to etch both the inter-layer insulation layers 12 and the conductive layers 11 using CF₄ gas. At this time, adding helium (He) gas may be advantageous for plasma turn on. Adding He gas allows the amount of the etch gas provided to be controlled, and thus, the etch rate may be controlled. Consequently, the process time for forming a target cell string may be decreased.

By etching the inter-layer insulation layers 12 and the conductive layers 11 at once using substantially the same gas, instead of separately etching each layer, generation of a stepped profile or staircase-like formation of the contact hole 14 may be prevented. Also, a vertical profile may be formed so that a limitation caused by a bowing effect may be improved when burying a conductive material for subsequently forming a channel.

Referring to FIG. 2C, insulation layers 15 are formed over the surface profile of the substrate structure. The insulation layers 15 are formed to create gate insulation layers for use in a subsequent etch process. For instance, the insulation layers 15 may include a three-layered structure of a nitride layer between two oxide layers (oxide/nitride/oxide or ONO).

Referring to FIG. 2D, a blanket etch process is performed to form gate insulation patterns 15A on sidewalls of the contact hole 14.

Referring to FIG. 2E, a conductive material is buried over the contact hole 14, and a planarization process is performed until the uppermost inter-layer insulation patterns 12A are exposed, thereby forming a channel 16. At this time, the conductive material may include polysilicon.

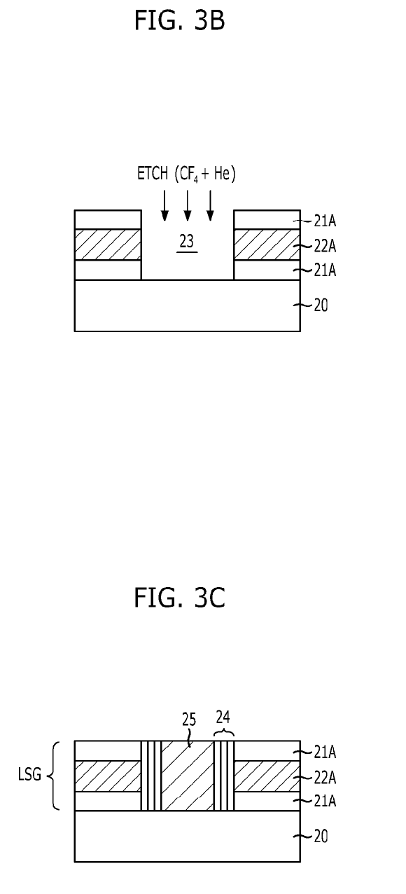

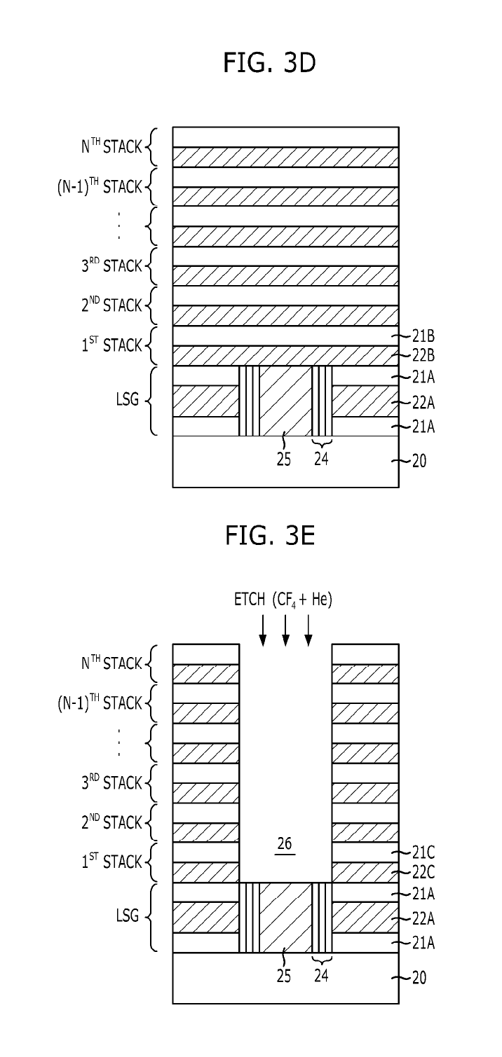

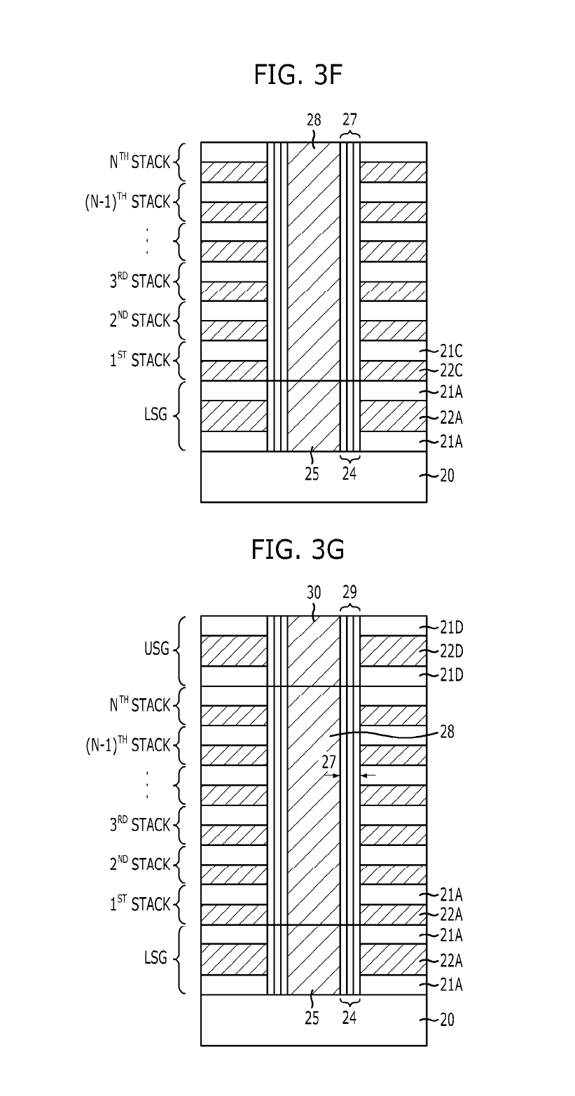

FIGS. 3A to 3G illustrate cross-sectional views of a method for fabricating a vertical channel type non-volatile memory device in accordance with a second embodiment of the present invention.

Referring to FIG. 3A, a first inter-layer insulation layer 21, a first conductive layer 22 for forming gate electrodes, and another first inter-layer insulation layer 21 are formed over a semi-finished substrate 20. The semi-finished substrate 20 generally includes required bottom structures, such as source lines. The first inter-layer insulations layers 21 and the first conductive layer 22 are formed to create a low select gate. The first inter-layer insulation layers 21 are formed to provide inter-layer insulation between memory cells. For instance, the first inter-layer insulation layers 21 may include oxide-based layers. The first conductive layer 22 is formed to create memory cells resulting from a subsequent etch process. The first conductive layer 22 may include a conductive material. For instance, the first conductive layer 22 may include polysilicon.

Referring to FIG. 3B, the first inter-layer insulation layers 21 (FIG. 3A) and the first conductive layer 22 (FIG. 3A) are etched to form a first contact hole 23 for forming a channel and first memory cells 22A insulated by first inter-layer insulation patterns 21A.

For instance, the first inter-layer insulation layers 21 and the first conductive layer 22 are etched at substantially the same time using one etch gas, rather than separately etching each layer.

Thus, an etch gas which etches both the first inter-layer insulation layers 21, including oxide-based layers, and the first conductive layer 22, including polysilicon, may be used. Also, a gas which may maintain a selectivity between the first inter-layer insulation layers 21 and the first conductive layer 22, for example, with a ratio of the different etching rates ranging from approximately 0.1 to approximately 2, may be used. For instance, the etch gas may include tetrafluoromethane (CF₄) gas. Etch reactions resulting from the use of CF₄ gas are as follows.

When etching polysilicon using CF₄ gas, CF₄ combines with silicon (Si) to generate silicon fluoride (SiF) while the etching process progresses (CF4+Si→SiF). When etching oxide using CF₄ gas, CF₄ combines with silicon dioxide (SiO₂) to generate carbon dioxide (CO₂) and SIF while the etching process progresses (CF₄+SiO₂→CO₂+SiF). Thus, it may be possible to etch both the first inter-layer insulation layers 21 and the first conductive layer 22 using CF₄ gas. At this time, adding helium (He) gas may be advantageous for plasma turn on. Adding He gas allows the amount of the etch gas provided to be controlled, and thus, the etch rate may be controlled. Consequently, the process time for forming a target cell string may be decreased. Furthermore, nitrogen (N) gas may be added to help dissociation of ions when forming plasma.

By etching the first inter-layer insulation layers 21 and the first conductive layer 22 at once using substantially the same gas, instead of separately etching each layer, generation of a stepped profile or staircase-like formation of the first contact hole 23 may be prevented. Also, a vertical profile may be formed so that a limitation caused by a bowing effect may be improved when burying a conductive material for subsequently forming a channel.

Referring to FIG. 3C, first gate insulation layers 24 are formed on sidewalls of the first contact hole 23. For instance, the first gate insulation layers 24 may include a three-layered structure of oxide/nitride/oxide (ONO).

A conductive material is buried over the first contact hole 23, and a planarization process is performed to form a first channel 25. At this time, the conductive material may include polysilicon.

Consequently, a low select gate (LSG) is formed.

Referring to FIG. 3D, second conductive layers 22B and second inter-layer insulation layers 21B are alternately formed over the substrate structure including the LSG. The second conductive layers 226 are formed to form memory cells using a subsequent etch process. The second conductive layers 22B include a conductive material. For instance, the second conductive layers 22B may include polysilicon. The second inter-layer insulation layers 21B are formed to provide inter-layer insulation between the subsequent memory cells. For instance, the second inter-layer insulation layers 21B may include oxide-based layers.

One second conductive layer 22B and one second inter-layer insulation layer 21B configure a stack, and the stacks are stacked to form a cell string. At this time, each of the second conductive layers 22B and the second inter-layer insulation layers 21B has a thickness ranging from approximately 50 Å to approximately 500 Å. Therefore, one stack including one second conductive layer 22B and one second inter-layer insulation layer 21B has a thickness ranging from approximately 100 Å to approximately 1,000 Å.

As semiconductor devices are becoming highly integrated, the number of stacks being stacked generally needs to be increased in order to include a larger number of memory cells in one cell string. Therefore, the stacks each including one second conductive layer 22B and one second inter-layer insulation layer 21B are repeatedly formed to form 1^{st}, 2^{nd}, 3^{rd}, (N−1)^{th}, and N^{th} stacks, where N is any positive integer. For instance, the stacks may be repeatedly formed approximately 2 to 128 times.

Referring to FIG. 3E, the second inter-layer insulation layers 21B (FIG. 3D) and the second conductive layers 22B (FIG. 3D) are etched to form a second contact hole 26 for forming a channel, and second memory cells 22C each insulated by a corresponding second inter-layer insulation pattern 21C.

For instance, the second inter-layer insulation layers 21B and the second conductive layers 2213 are etched at substantially the same time using one etch gas, rather than separately etching each layer.

Thus, the etching process uses CF₄ gas, which may etch both the second inter-layer insulation layers 21B, including oxide-based layers, and the second conductive layers 22B, including polysilicon. In particular, a selectivity between the second inter-layer insulation layers 21B and the second conductive layers 22B may be maintained with a ratio of the different etching rates ranging from approximately 0.1 to approximately 2 by using CF₄ gas as the etch gas. Etch reactions resulting from the use of CF₄ gas are as follows.

When etching polysilicon using CF₄ gas, CF₄ combines with Si to generate SIF while the etching process progresses (CF₄+Si→SiF). When etching oxide using CF₄ gas, CF₄ combines with SiO₂ to generate CO₂ and SiF while the etching process progresses (CF₄+SiO₂→CO₂+SiF). Thus, it may be possible to etch both the second inter-layer insulation layers 21B and the second conductive layers 2213 using CF₄ gas. At this time, adding He gas may be advantageous for plasma turn on. Adding He gas allows the amount of the etch gas provided to be controlled, and thus, the etch rate may be controlled. Consequently, the process time for forming a target cell string may be decreased. Furthermore, N gas may be added to help dissociation of ions when forming plasma.

By etching the second inter-layer insulation layers 21B and the second conductive layers 22B at once using substantially the same gas, instead of separately etching each layer, generation of a stepped profile or staircase-like formation of the second contact hole 26 may be prevented. Also, a vertical profile may be formed so that a limitation caused by a bowing effect may be improved when burying a conductive material for subsequently forming a channel.

Referring to FIG. 3F, second gate insulation layers 27 are formed on sidewalls of the second contact hole 26. For instance, the second gate insulation layers 27 may include a three-layered structure of ONO.

Next, a conductive material is buried over the second contact hole 26, and a planarization process is performed until the uppermost second inter-layer insulation patterns 21C are exposed to form a second channel 28. At this time, the conductive material may include polysilicon.

Referring to FIG. 3G, a process substantially the same as the one used to form the LSG as shown in FIGS. 3A to 3C is performed to form an upper select gate (USG).

At this time, reference denotations 21D, 22D, 29, and 30 represent third inter-layer insulation patterns 21D, third memory cells 22D, third gate insulation layers 29, and a third channel 30, respectively.

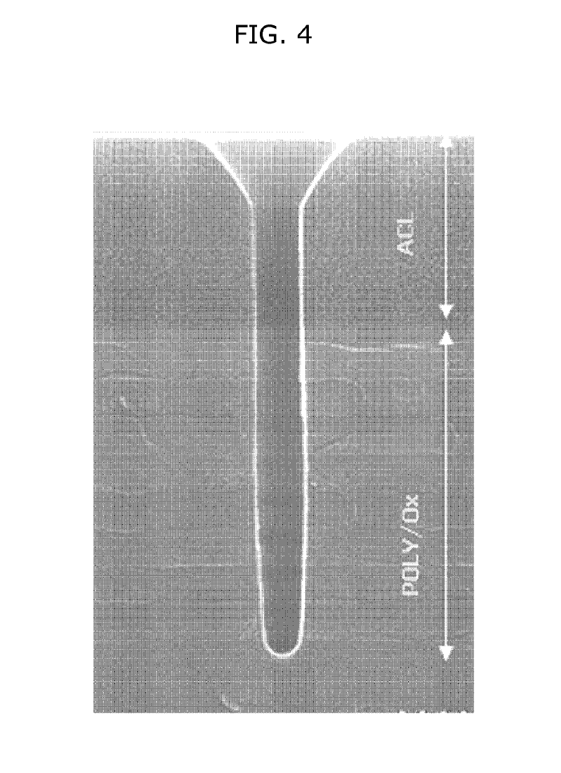

FIG. 4 illustrates a micrographic view showing stack structures in accordance with the embodiments of the present invention.

Referring to FIG. 4, an etch process is performed to form a vertical profile without forming a stepped formation between polysilicon layers and oxide-based layers.

The method for fabricating a vertical channel type non-volatile memory device in accordance with the embodiments of the present invention improves the profile of a contact hole to a vertical profile when etching stacks having materials different from each other by etching the stacks using a gas which may etch both of the different materials in one process.

While the present invention has been described with respect to the specific exemplary embodiments, it will be apparent to those skilled in the art that various changes and modifications may be made without departing from the spirit and scope of the invention as defined in the following claims.

What is claimed is:

1. A method for fabricating a vertical channel type non-volatile memory device, comprising:
repeatedly forming stacks of conductive layers and inter-layer insulation layers over a substrate; and
performing an etch process using an etch gas which etches both the conductive layers and the inter-layer insulation layers to form a contact hole exposing the substrate,
wherein the etch gas maintains a selectivity between the inter-layer insulation layers and the conductive layers with a ratio of different etching rates ranging from approximately 0.1 to approximately 2.

2. The method of claim 1, wherein the conductive layers comprise polysilicon.

3. The method of claim 1, wherein the inter-layer insulation layers comprise oxide-based layers.

4. The method of claim 2, wherein the etch gas comprises tetrafluoromethane (CF₄) gas.

5. The method of claim 3, wherein the etch gas comprises tetrafluoromethane (CF₄) gas.

6. The method of claim 1, wherein the performing of the etch process to form the contact hole comprises adding helium (He) gas to the etch gas.

7. The method of claim 1, wherein the performing of the etch process to form the contact hole comprises adding nitrogen (N) gas to the etch gas.

8. The method of claim 1, wherein the stacks are repeatedly formed approximately 2 to 128 times.

9. The method of claim 1, wherein each stack has a thickness ranging from approximately 100 Å to approximately 1,000 Å.

10. The method of claim 1, further comprising:
forming gate insulation layers on sidewalls of the contact hole; and
burying a conductive material over the contact hole to form a channel.

11. The method of claim 10, wherein the gate insulation layers comprise a three-layered structure of a nitride layer between two oxide layers.

12. The method of claim 10, wherein the conductive material comprises polysilicon.
